(19) United States
(12) Patent Application Publication
(10) Pub. No.: US 2015/0201504 A1
(43) Pub. Date: Jul. 16, 2015

(54) COPPER PARTICLE COMPOSITION

(71) Applicant: Applied Nanotech, Inc., Austin, TX (US)

(72) Inventors: ZVI YANIV, AUSTIN, TX (US); XUEPING LI, AUSTIN, TX (US); JAMES P. NOVAK, AUSTIN, TX (US)

(21) Appl. No.: 14/597,649

(22) Filed: Jan. 15, 2015

Related U.S. Application Data
(60) Provisional application No. 61/927,706, filed on Jan. 15, 2014.

(51) Int. Cl. H05K 3/38; H05K 3/10; H05K 3/12

(52) U.S. Cl. CPC H05K 3/386; H05K 3/125; H05K 3/1291; H05K 3/108

(57) ABSTRACT

Conductive patterns are formed using formulations containing metallic particles, which may be copper. These metallic particles may be coated with a binder material that improves adhesion during photosintering of the formulations. The binder contains chemistry suitable for it to be removed from the particles in a separate process such as drying or thermal sintering. The coating is a non-volatile organic compound attached to the metallic particles with a minimum thickness oxide coating. The organic coating improves a coefficient of thermal expansion value match between the metallic particles and the substrate, which may be polymeric.

This application claims priority to U.S. Provisional Patent Application Ser. No. 61/927,706, which is hereby incorporated by reference herein.

### TECHNICAL FIELD

The present disclosure relates in general to metallic compositions, and in particular, to metallic compositions in which the metal particles possess an organic coating for functioning as a binder during a process for forming conductive films.

### BACKGROUND AND SUMMARY

This section is intended to introduce various aspects of the art, which may be associated with exemplary embodiments of the present disclosure. This discussion is believed to assist in providing a framework to facilitate a better understanding of particular aspects of the present disclosure. Accordingly, it should be understood that this section should be read in this light, and not necessarily as admissions of prior art.

There are many challenges to manufacturing electronic devices using additive processing, such as in the field of printed electronics. Several types of printing methods can be used to apply films and/or layers of metallic compositions (e.g., inks and/or pastes) onto various substrates, which are then further processed to produce conductive metallic traces on these substrates. Many of the substrates utilized in printed electronics are made of low temperature materials, such as plastics and polymers (also referred to herein as polymeric materials, which include polyimide and PET), low temperature glass, and combinations of these substrates with additional coatings or materials, all of which cannot withstand temperatures exceeding about 300° C. In most cases, the maximum temperature should not exceed about 150° C.

These substrate limitations define many requirements for the processing of compositions used in printed electronics. A primary requirement is that a thermal sintering temperature be appropriate for the substrates or coated substrates. To achieve these low temperature thermal sintering conditions, the compositions may be designed with chemical and physical compositions suitable for minimum energy to be applied for the thermal sintering process to be effective.

Thermal sintering occurs when individual particles transition into connected films by a multi-stage melting mechanism. When sufficient energy is applied to the particles, the surfaces of the particles begin to melt. This allows neighboring particles to coalesce with interparticle connections. This process is also referred to as “necking.” The application of more energy allows the liquid-solid phase interface to propagate toward the center of the particles. Increased surface melting allows for increased volume connections between particles. Full particle melting along with sufficient time for the physical particle reorganization due to liquid flow can result in complete near-solid, bulk conductors.

Using smaller particles, such as nanoparticles, in the compositions can lower the overall energy requirements for thermal sintering. Due to melting point depression, the smaller the nanoparticle, the lower the melting point. It is not uncommon for metal nanoparticles with a diameter less than 50 nanometers (“nm”) to have a melting point less than 200° C.

A challenge to utilizing these smaller nanoparticles in metallic compositions for print-based manufacturing is stability. The nanoparticles, such as those made of copper, silver, gold, nickel, aluminum, platinum, and iron, are highly susceptible to oxidation. In most cases, the oxide coatings are non-conductive. Such metal oxide coatings are very stable and difficult to remove from the nanoparticles.

Photosintering (which is different than mere thermal sintering), in addition to melting the particles, removes surface oxides of metals through a photoreduction process. The photoreduction process involves a photoelectron transfer reaction to transfer the electron from the negatively charged oxide to the positively charged metal (e.g., to the positively charged copper to form uncharged metallic copper). Such a photoelectron transfer process is the result of photoexcitation, which is an electron excitation by photon absorption into the band gap of the metal oxide. It is this process that results in the electron transfer. This is not the same as a chemical reduction process, which is actually the result of a change in oxidation state (in which the actual transfer of electrons may never occur). The removal of surface oxides allows the molten metal on the surfaces of the particles to more easily flow into adjacent particles to create improved necking and electrical contact during the melting process. For a further discussion of such a photoreduction process, please refer to U.S. published application nos. 2008/0286488 and 2009/0311440, and PCT application no. PCT/US2013/049635, which are hereby incorporated by reference herein.

Ink and/or paste formulations often include a solvent or vehicle, formulation modifiers, and metallic particles. When formulating an ink and/or paste of metallic particles, the chemistry of the ink and/or paste is often used to protect the surfaces of the particles from oxidation. This chemistry contains moieties that protect the particles against oxidation, provides steric or electrostatic repulsion between adjacent particles that prevents agglomeration, and/or provides solvent interaction to maintain or modify viscosity as well as aid in modifying the contact angle and surface energy interactions with the substrate to which they are applied. Many individual formulations may be required for optimization onto different substrate materials.

A challenge with these chemical moieties is that the remaining, residual chemistry after the initial solvent removal and drying process can interfere with the photosintering process and cause adhesion problems.

### BRIEF DESCRIPTION OF THE DRAWINGS

FIG. 1 illustrates a process in accordance with embodiments of the present invention;

FIG. 2A illustrates an apparatus in accordance with embodiments of the present invention;

FIG. 2B illustrates a process in accordance with embodiments of the present invention.

### DETAILED DESCRIPTION

Aspects of the present disclosure describe a nanoparticle coating and a process to thermal sinter and/or photosinter the particles, which can facilitate roll-to-roll processing, improve composition (e.g., inks and/or pastes) stability, control oxide formation, and/or improve adhesion to the substrate. The results of these factors combine to improve the conductivity of the resultant metallic film.

Thermal sintering occurs when heat energy is applied to a metallic composition deposited as a film/layer onto a substrate. The heat energy can be from the infrared spectrum and applied by lamps, heating elements, or other thermal sources. The heat energy is simultaneously absorbed by the particles and substrate. The heat energy is relatively low in comparison to shorter wavelength energies, and absorbs more slowly due to the fact that many metals are infrared reflectors. Thermal sintering typically takes many minutes, even tens of minutes, to complete the thermal sintering process.

Photosintering involves multiple mechanisms. The particles that are suitable for being photosintered will have an optical absorbance band. Optical absorbance in the visible region will be exhibited on such a material as a colored material. For example, copper (“Cu”) particles of diameter greater than 400 nanometers (“nm”) will have an orange-red appearance. Larger and larger diameter copper particles exhibit more and more of a typical copper color. Silver particles can have a greenish or yellow appearance depending on diameter. When the diameters of metal nanoparticles are less than 200 nm, their optical absorbance may be greater due to high extinction coefficients generated by free electrons on the metal surfaces that are quantum confined. This quantum confinement generates a surface plasmon wave at a resonance frequency. The frequency of resonance dictates the light absorbance spectrum and the nanoparticle color. Many metal nanoparticle dispersions with particle diameters below 80 nm are brown or black in color due to the large, broad absorbance due to a distribution of diameters. The broad absorbance covers a wide range of wavelengths for light interaction.

When light energy is absorbed by the particles, it is converted internally to heat energy in an effort to dissipate. The heat energy is dissipated through the various mechanisms of convection, conduction, and radiation.

When small particles (of micro- and nano-dimensions) have surface coatings, they can be considered to possess a core-shell structure. In embodiments of the present disclosure, the shell can be an organic coating or an oxide of the core material. (In the example of copper particles, the surfaces can be coated with copper oxides.) These coatings can have different optical absorbance values than that of the core material. Oxide layers on the surfaces of particles can undergo reactions upon the absorbance of light. (In the example of copper, copper oxide can be photoreduced to metallic copper(0), i.e., a complete metallic surface on the particle.) Thus, the removal of the oxide layer facilitates surface melting on the particle.

If the light energy delivered to the particle is of a high intensity, a situation exists where the internal conversion to heat in the particle is faster than its ability to dissipate the heat. In this case, the internal temperature of the particle will rise. If the intensity of light is high enough to heat the particles, and long enough to maintain and continue the rise in temperature, the particles can reach a sufficiently high enough temperature that they will melt. A description of this mechanism is further described hereinafter. An advantage of photosintering is that the light can be of a controlled pulse width and can rapidly bring the particles to a point of melting in millisecond time scales. Additionally, when the light is removed, the particles rapidly cool.

Often, the optical absorbance spectrum of the substrates is such that they do not absorb the optical energy and generate heat. Thus, it is possible to preferentially heat the particles on the surface without heating the substrate material. The only heat imparted onto the substrate is the conduction transfer from the particles to the substrate. This independent heating of the particles separate from the substrate is not possible with thermal sintering.

Thermal sintered particle films are characterized by local surface melting of adjacent particles where the surface melting connects the particles. Increasing the surface energy of the individual particles can reduce the total energy threshold required to thermal sinter these particles. The total energy of a particle is related to the total cohesive force within a particle. The cohesive force is related to the bonding energy of adjacent atoms within a particle. Lindemann's Criterion describes the relationship between cohesive force and thermal energy. Lindemann's Criterion states that the melting temperature of any material is proportional to its overall cohesive energy. Lindemann's Criterion explains the process by which surfaces of bulk materials can melt at lower temperatures than their full bulk material. It is this phenomenon that enables metal particle films to be thermal sintered into conductive films.

The surface energy of metal particles can be increased by several methods, including reduction of particle size, secondary metal coatings, chemical functionalization, alloy layers, and “core-shell” particle structures. Changing the surface energy also changes the cohesive forces of the surface atoms. Changing the cohesive force will change the energy required to melt the surface of the particle.

Surface energy is related to particle size. As the particle size decreases, there is a relative increase in the ratio of the total number of surface atoms relative to the total number of atoms in the bulk. This means that a particular surface atom has fewer neighboring atoms. Therefore, the total cohesive energy of a surface atom is reduced due to the reduction in the total cohesive bonds. Due to the decrease in energy loss of a given atom to maintain cohesive bonds to its neighboring atom, the total surface energy increases.

Surface energy can be manipulated by surface coatings. These coatings can be in the form of chemical functionalization. For example, adding an electron-donating molecule can increase the surface energy. Likewise, addition of an electron-withdrawing molecule can decrease the surface energy.

In addition to surface functionalization, particle surface energy can be manipulated with light. Colored material has an optical absorbance spectrum that determines which wavelengths of light are absorbed and which wavelengths are reflected. Each material has an extinction coefficient that defines how much light is absorbed at each particular wavelength. The wavelength spectra and the extinction coefficient are dependent on particle size. Smaller particles have higher energy and therefore have lower wavelength spectra and a larger extinction coefficient. Larger particles have lower energy and therefore have higher wavelength spectra and a reduced extinction coefficient. When light hits the surface of the particle, the overall energy of the surface is increased due to this absorbance spectrum. The more energy that is applied by exposure to more photons, the more reactive the surface becomes and the more energy is dissipated into the particle as heat. When a given threshold is reached, there can be sufficient energy for chemical reactions to take place or a phase change to take place, such as a solid to liquid transition. The light penetration is shallow on large particles. Therefore, the light induced effects are limited to the surfaces of large particles. A mixture of particles with a large distribution of sizes can create a distribution in how the light energy is absorbed and dissipated within a particular particle and its neighboring particles.

In a mixture of large and small particles, each size range of particles can serve a specific function. Smaller particles absorb more light due to their increased extinction coefficient. Smaller particles also absorb shorter wavelength light that has higher energy. This increased energy creates more heat within the smaller particles compared to the larger particles. The increased energy within the smaller particles defines a situation where smaller particles will begin to surface melt upon exposure to intense light. Broad spectrum light emitted with a high intensity is good for photosintering a mixture of particles. If the energy of light is applied in a uniform manner, and the distribution of particles has a unique mixture of large and small sizes, the smaller particles can melt into the larger particles to produce a conductive pathway through the resulting film.

There are limits to the light absorbance mechanism for particle surface melting. If not enough photons are absorbed, or the overall time period of light exposure is too short, the particle surfaces will not melt, and the film will not be photosintered, nor be conductive. If the light is applied too quickly and/or too intensely, the light absorbance is too fast, and the particles will heat up so quickly that they will ablate from the surface of the substrate. In this case, the surface adhesion of the resistant film is poor. The threshold between these two extremes is narrow and could be described as a step function, meaning there is very little energy intensity difference between what is too low and does not create a conductive film and what is too high and ablates material from the substrate surface. Ideally, a large process window would exist allowing for the capability to create a conductive film that has strong adhesion to the substrate surface.

In aspects of the present disclosure, the distribution of particle sizes plays an important role in enabling effective photosintering of particles. The smaller particles still absorb light energy and heat up. However, in combination with the larger particles, there is a new mechanism enabled whereby some of the heat energy of the smaller particles is transferred to the larger particles. Smaller particles can have high latent heat transfer coefficients. This transfer of energy provides a buffering effect of the temporal temperature rise. The result is an ability to create a conductive film without risk of adhesion loss. Chemical surface modifications, metal films, and nanoparticle coatings on non-nanosized metal particles can have similar effects at changing the aforementioned step function between non-conductive films and complete film ablation.

An advantage of photosintering compared to traditional thermal sintering is an ability to complete light-induced reactions on the surfaces of the particles as part of the light absorbance. Photoreduction removes oxide layers on metal particles by converting these to the parent metal upon exposure to sufficient intensity and proper wavelength of light energy. New absorbance spectra can be created in situ by the removal of oxide coatings. Oxide coatings have high melting points. Removal of oxide layers enables clean metal surfaces of individual particles to melt into their nearest neighboring particles. For example, copper oxide can be converted to copper(0) metal surfaces.

In aspects of the present disclosure, chemical surface coatings deposited onto particles may be inorganic or organic. The inorganic coatings may be different metals than the particles used to make the metallic ink or paste. Inorganic coatings may also be metal oxide, nitride, sulfides, or other mixed chemistries. Organic coatings may come from self-assembled monolayers, surface-adsorbed organic molecules, polymer materials, and/or solvents that interact with the particle surface. The specific chemistry of the organic coating determines how strongly bonded the organic coating is to the surface of the metallic particle. These coatings may be applied to the particles during synthesis or added to the surfaces of the particles during the ink and/or paste formulation and processing.

The organic coatings may serve functions of protection from oxidation, prevention of agglomeration, control over liquid viscosities, and/or control over gravitational settling while in the ink and/or paste phase. The organic coatings may serve additional functions once the ink and/or paste has been applied to a surface or substrate and the primary volatile solvents have been removed. At this point, the surface organic coatings may prevent oxidation resulting from exposure to ambient atmospheres, facilitate the drying process, control surface energy and ink and/or paste spreading during the application process, and/or facilitate adhesion between the particles, adjacent particles, and the substrate. In the case of adhesion promotion, the coating may act as a binder.

In aspects of the present disclosure, a metallic composition (e.g., an ink and/or paste deposited on a substrate) is composed of metallic particles, a binder (e.g., as a surface coating on the metallic particles), and a solvent system suitable for application to a polymeric substrate. The solvents may be removed using a drying process, leaving the binder (which may now be partially decomposed as described herein) and metallic particles. The binder may be further decomposed (e.g., using a higher temperature thermal sintering process in a low oxygen concentration environment). During the drying stage and/or during this higher temperature process, the binder protects the metallic particles from oxidation. The oxygen content during a drying stage may be between 10 and 1000 parts per million (“ppm”) with the remainder an inert gas. This low oxygen environment is still sufficient to decompose the binder due to oxidation. The residue of the binder remains to protect the metallic particles from oxidation beyond a native oxidation coating. After this thermal conversion process (drying and/or thermal sintering), the metallic particles are photosintered to convert them into a conductive layer on the substrate.

Referring to Table 1, in a first set of examples of the foregoing, copper nanoparticles coated with an organic binder coating were mixed with a solvent. The resulting low viscosity liquid was applied using an inkjet printer to both polyimide and polyethylene terephthalate (“PET”) substrates. The samples were dried at about 100° C. for 10 minutes to remove the solvent. The samples were further processed using three different methods. The first method utilized only photosintering. The second method utilized only thermal sintering. The third method utilized thermal sintering followed by photosintering. The thermal sintering only method resulted in a conductive film with a similar resistivity value as the photosintering only method. The samples that were thermal sintered followed by photosintering (i.e., the third method) in two separate steps resulted in a film having a further reduced resistivity. In some examples, the resistivity was reduced by an order of magnitude. In all examples, when loading of the copper nanoparticles in the composition was lower than 50 wt. % and/or the deposited Cu film thickness was less than or equal to 3 microns, the adhesion of the processed Cu film on polyimide achieved a full adhesion score of 5 B out of a 0 B-5 B range on an ASTM D 3359 style tape adhesion test throughout all curing methods. In all examples, the adhesion on PET was poor due to the mismatched coefficient of thermal expansion (“CTE”) value between the Cu film and the PET substrate, scoring a 0 B on an ASTM D 3359 style tape adhesion test. In such a tape adhesion test, scoring, or classifications, are as follows: 0 B means greater than 65% of the material was removed; 1 B means 35%-65% of the material was removed; 2 B means 15%-35% of the material was removed; 3 B means 5%-10% of the material was removed; 4 B less than 5% of the material was removed; and 0 B means 0% or substantially none of the material was removed when tape was applied and then peeled off. Note that thermal sintering of Cu nanoparticles on PET substrates is not possible because the melting temperature of the Cu particles is higher than the melting temperature of PET.

TABLE 1

| Printing Method | InkJet Printing | | |
|---|---|---|---|
| Formulation | Low Viscosity | | |
| Processing Method | First Method: | Second Method: | Third Method: |
| | Photosintering | Thermal Sintering | Thermal Sintering |
| | Only | Only | plus Photosintering |
| Processing Temperature | Room | 250° C. | 200° C. (N₂/O₂ |
| and Environment | Temperature/ | (N₂/H₂ | Environment)- >250° C. |
| | Ambient | Environment) | (N₂/H₂ Environment) |
| | Environment | | for Thermal Sintering + Room |
| | | | Temperature/Ambient Environ- |
| | | | ment for Photosintering |
| Resistivity (ohm-cm); | 1-5 × 10⁻⁵ | 1-5 × 10⁻⁵ | 5-9 × 10⁻⁶ |
| Obtained from deposition | | | |
| on polyimide substrate | | | |
| Adhesion of film on | 5B | 5B | 5B |
| polyimide substrate | | | |
| Adhesion of film on PET | 0B; | Method Not | Method Not |
| substrate | 100% Ablation | Possible | Possible |

Referring to Table 2, in another set of examples of aspects of the disclosure, copper nanoparticles coated with an organic binder were mixed with a solvent. The resulting high viscosity composition was applied using a screen printer to both the polyimide and PET substrates. The samples were dried at about 100° C. for 10 minutes to remove the solvent. The samples were further processed using three different methods. The first method utilized only photosintering. The second method utilized only thermal sintering. The third method utilized thermal sintering followed by photosintering. The thermal sintering only method resulted in a conductive film. The photosintering only method caused complete film liftoff from the substrates (e.g., 100% ablation). Without adhesion, this sample could not be measured for resistivity. The samples that were thermal sintered followed by photosintering (i.e., the third method) in two separate steps provided reduced resistivity. In some examples, the resistivity was reduced by an order of magnitude.

As the loading of copper nanoparticles in the composition increased, the thicker deposited (e.g., screen printed) Cu film (e.g., greater than 5 microns) became difficult to be photosintered, resulting in partial or 100% blow-off, or ablation. Poor adhesion was also observed from thermally sintered only samples due to the interfacial stress between Cu particles during the thermal sintering process.

The adhesion using thermal sintering followed by photosintering (i.e., the third method) on the polyimide substrate was excellent, scoring a 5 B on an ASTM D 3359 style tape adhesion test. In all examples, the adhesion on PET substrate was poor due to the difference in CTE value between the Cu film and the PET substrate, scoring a 0 B on an ASTM D 3359 style tape adhesion test. As previously noted, thermal sintering of Cu nanoparticles on PET substrate is not possible because the melting temperature of the Cu particles is higher than the melting temperature of PET.

TABLE 2

| Printing Method | Screen Printing | | |
|---|---|---|---|
| Formulation | High Viscosity | | |
| Processing Method | First Method: | Second Method: | Third Method: |
| | Photo sintering | Thermal Sintering | Thermal Sintering |
| | Only | Only | plus Photosintering |
| Processing Temperature | Room | 250° C. | 200° C. (N₂/O₂ |
| and Environment | Temperature/ | (N₂/H₂ | Environment)- >250° C. |
| | Ambient | Environment) | (N₂/H₂ Environment) |
| | Environment | | for Thermal Sintering + Room |
| | | | Temperature/Ambient Environ- |
| | | | ment for Photosintering |
| Resistivity (ohm-cm); | NA | 5-9 × 10⁻⁵ | 5-9 × 10⁻⁶ |
| Obtained from deposition | 100% Ablation | | |
| on polyimide substrate | | | |
| Adhesion of film on | 0B | ~0B | 5B |
| polyimide substrate | | | |
| Adhesion of film on PET | 0B | Method Not Possible | Method Not Possible |
| substrate | 100% Ablation | | |

In many cases, with the processing of the relatively thick (i.e., high viscosity), screen printed samples, the adhesion was poor. This was generally caused by the CTE mismatch between the copper metallic film deposited on the lower CTE polymeric substrate. The samples prepared by photosintering only had complete sample ablation. This was caused by the large volume of binder material that was rapidly removed during the photosintering process. The thicker higher viscosity films cannot dissipate the off gassing products from the reaction like thinner lower viscosity films deposited using an inkjet printer. This means that the removal of gaseous products also removes the copper particles from the surface due to rapid expansion mechanisms.

The screen printed samples prepared with only thermal sintering did not have complete removal or decomposition of the binder material. The adhesion was poor due to the incomplete conversion of the binder material. These samples were less conductive compared to the thermal sintering plus photosintering samples.

As indicated in Table 2, the screen printed samples prepared by thermal sintering and followed by photosintering showed excellent resistivity values and high adhesion onto polyimide substrates. In this example, the binder materials were first decomposed and some lower-molecular weight by-products remained to protect against oxidation. The decomposition may be accomplished by heating the samples in an oxygen containing environment. If the oxygen content is kept below 0.5%, oxidation of the particles will be minimized. The oxygen is allowed to react with the hydrocarbon-based binders to create secondary by-products. When the sample was then further photosintered, these byproducts were converted to help with adhesion. The conversion process of the byproducts can include polymerization, photoreduction, and cross-linking reactions that can bridge the particles and substrates enhancing adhesion. The photosintering process can remove surface oxides. A result is that thermal sintering plus photosintering provided excellent adhesion and low resistivity required for printed electronic devices.

Referring to Tables 3 and 4, in the following examples, multiple copper compositions with viscosities above 30 kCp were made to test adhesion onto PET and polyimide substrates. Two of the three Cu compositions noted below incorporated a binder into the composition formulation.

Composition #1: A composition formulated with Cu particles having an average diameter less than 3 microns and greater than 1 micron (hereinafter referred to as “micro-Cu particles”) containing 80 wt. % Cu, containing a solvent (e.g., Terpinol), without being modified with an ethyl cellulose (“ETC”) binder.

Composition #2: A composition formulated with Cu particles having an average diameter less than 100 nanometers and greater than 10 nanometers (hereinafter referred to as “nano-Cu particles”), containing a solvent (e.g., benzyl alcohol), wherein the nano-Cu particles are modified with an ETC binder (e.g., the Cu particles are coated with the ETC binder).

Composition #3: A composition formulated with micro-Cu particles, containing a solvent (e.g., Terpinol), wherein the micro-Cu particles are modified (e.g., coated) with an ETC binder.

The sample compositions with these three formulations were deposited (e.g., noted herein as films, coatings, or layers) onto polyimide and PET substrates (e.g., using a draw-down rod technique). After coating the substrates with the compositions, the samples were dried (e.g., at 100° C. for 30 minutes) to remove the volatile solvent. Note that embodiments of the present disclosure may also thermal sinter the samples after the drying stage. The samples were then photosintered (e.g., using a Xe-arc discharge lamp).

As shown in Table 4, the Composition #1 deposited with a thin coating (e.g., <2 microns) on a polyimide substrate was photosintered and achieved a resistivity of about 6-7×10⁻⁶ ohm-cm with a full score of adhesion (i.e., 5 B on an ASTM D 3359 test). And, as also shown in Table 4, if the deposited composition thickness reaches approximately 10 microns or greater, a typical photosintering power (e.g., 1500 J) will be not strong enough to penetrate the Cu coating; the result is that the Cu coating can only be partially photosintered. In this example, the top surface of the deposited copper coating is photosintered and conductive, while the lower underneath portion of the deposited copper coating adjacent to the substrate is not photosintered. This leads to a weak adhesion of the film on the substrate (i.e., the surface of the photosintered film can be removed with scotch tape). This is shown in Table 4 where the application of such a thick coating of the Composition #1 on a PET substrate has an adhesion score of 0 B.

When a Cu particles-based composition is modified with an ETC binder, it can be applied to a PET substrate with an approximately 4-5 micron thickness and photosintered throughout the applied coating. As shown in Table 4, the resulting copper film (after photosintering) achieves a resistivity about of 7.7×10⁻⁵ ohm-cm with a 5 B adhesion score for the Composition #2, and a resistivity of about 3×10⁻⁴ ohm-cm with a 4 B adhesion score for the Composition #3.

Referring to Table 3, Cu and polyimide both have a (CTE) value in the range of 16-17 ppm/° K, while PET and most engineered polymer materials have a CTE value in the range of 50-200 ppm/° K. That explains why the above-noted Composition #1 without an ETC binder has good adhesion on a polyimide substrate and would have poor adhesion on a PET substrate and other non-polyimide plastic materials, such as polycarbonate (“PC”), polystyrene (“PS”) and polyvinyl chloride (“PVC”). The ETC-modified compositions (i.e., Compositions #2 and #3) have good adhesion on PET and other non-polyimide materials, but poor adhesion on polyimide. The CTE values of copper, polyimide, PET, and other plastic materials are listed in Table 3.

TABLE 3

| | Coefficient of Linear |
|---|---|
| | Temperature Expansion |
| | (CTE, ppm/° K) |
| Copper | 16.6 |
| Polyimide | 16.7 |
| Polyethylene Terephthalate (“PET”) | 59.4 |
| Polycarbonate (“PC”) | 70.2 |
| Polystyrene (“PS”) | 70 |
| Polyvinyl chloride (“PVC”) | 50.4 |

As a result, when there is a significant mismatch of CTE between the applied copper film and the underlying substrate, there will be poor adhesion. As shown in Tables 1 and 2, no adhesion was obtained from photosintered Cu films on PET. The substrate has a fixed CTE; therefore, the CTE of the composition should be modified to better match the CTE of the particular substrate, or the two would be considered incompatible due to poor adhesion. In aspects of the disclosure, ETC is introduced to the Cu composition to change the CTE value of the Cu composition such that it will better match to the CTE of the substrate. ETC has a high CTE value of 108-198 ppm/° K. Mixing ETC in different ratios within a copper composition raises its CTE. As a result, the adhesion of such modified Cu compositions on PET, PC, PS, and PVC is improved with the addition of ETC. Note that the Compositions #2 and #3 with the ETC added into the formulations had improved adhesions to PET, as shown in Table 4. Composition #1 did not have ETC in the formulation and thus had poor adhesion to PET.

TABLE 4

| Composition | Substrate | Adhesion | Thickness | Resistivity (ohm-cm) |
|---|---|---|---|---|
| Composition #1 (with | polyimide | 5B | <2 microns | 6-7 × 10⁻⁶ |
| micro-Cu particles) | PET | 0B | 10 microns | 9.6 × 10⁻⁶ |
| Composition #2 (with | PET | 5B | 4-5 microns | 7.7 × 10⁻⁵ |
| nano-Cu particles) | | | | |
| Composition #3 (with | PET | 4B | 4-5 microns | 3 × 10⁻⁴ |
| micro-Cu particles) | | | | |

As shown in Table 4, with the addition of the CTE modifier (e.g., ETC) into the existing composition, the Cu-to-substrate adhesion of a photosintered Cu film on PET dramatically improved: 4 B-5 B of adhesion achieved compared to no adhesion (i.e., 0 B) from the non-ETC modified Composition #1. This is because ethyl cellulose (“ETC”) has many hydroxyl and ethoxy chemical groups on the surface of the molecular chain. These hydroxyl groups chemically interact with the carbonyl groups in the PET material through hydrogen bonding to thus improve the adhesion. However, the same hydroxyl and ethoxy groups will not chemically interact with the imide (nitrogen containing) moiety on the polyimide polymer. If a formulation is made without ETC (e.g., Composition #1), it will have poor adhesion to PET as evidenced by the adhesion score of 0 B in Table 4. If a formulation is made with ETC (e.g., Compositions #2 and #3), the adhesion to a PET substrate will be stronger (see Table 4). Therefore, the binder interaction of the particles and the formulation can dictate adhesion properties of the copper composition onto various substrates.

The copper compositions described herein may be processed onto substrates separating the different steps. This allows for partially processed substrates that can be processed on one manufacturing line (e.g., the aforementioned drying and/or thermal sintering steps) and then subsequently transferred to a different line for the photosintering process. For example, a pattern of a composition as disclosed herein was printed onto a polymeric substrate (e.g., a continuous roll) using one of the metallic compositions described herein. This composition was then dried and partially thermal sintered using a thermal process similar to those disclosed with respect to Table 1 and Table 2. The sample may then be stored or moved onto a separate apparatus for photosintering without issues of oxidation. The photosintering process was then completed (e.g., at high speed using a pulse coordinated flash system). The two processes were separated due to the differences in processing speed dictated by the various equipment.

In another example, a thin layer of polymer (e.g., polyimide or PET) was applied to a glass substrate. This layer of polymer served as an adhesion promoter to a then deposited composition comprising binder-coated metallic particles, which was thermal sintered at about 350° C. for 60 minutes. Good adhesion (3 B on an ASTM D 3359 test) was achieved between the deposited and sintered composition and the polyimide pre-coated glass substrate; a resistivity of 5.8×10⁻⁵ ohm-cm was achieved. The chemistry of the binder interacted with the polymeric substrate, not the inorganic glass substrate. A control sample without the polyimide pre-coating was also processed. Poor adhesion (0 B on an ASTM D 3359 test) was observed for a Cu composition deposited on glass after thermal sintering at 350° C. for 60 minutes.

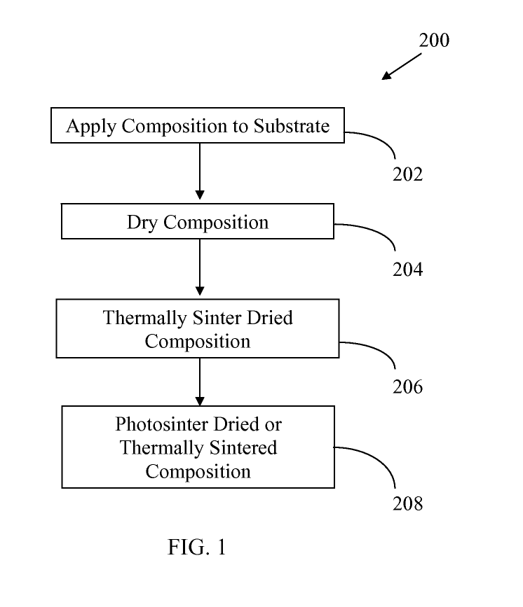

FIG. 1 illustrates a process 200 for forming a low resistivity conductor from a liquid metallic composition produced in accordance with embodiments of the present disclosure. In process block 202, a metallic composition as disclosed herein is applied (e.g., deposited) to a substrate (as disclosed herein). In process block 204, the substrate may be heated (e.g., in an oven for about 60 minutes at about 100° C.) to dry the composition by removing the solvents, which have been selected to produce a desired viscosity for the metallic composition (e.g., an ink with a lower viscosity for depositing of the metallic composition utilizing inkjet printing, or a paste with a higher viscosity for depositing of the metallic composition utilizing screen printing). Note that any suitable solvent(s) may be utilized to evaporate during the drying stage, with a selection of suitable solvents dependent upon the desired drying temperature.

In process block 206, the dried composition may be thermally sintered. In an example, the thermal sintering 206 may include the following steps. A substrate with a dried metallic composition is loaded into a quartz tube at room temperature. The quartz tube is evacuated (e.g., to about 100 mTorr). The quartz tube may be heated (e.g., to about 350° C.) and purged with a forming gas (e.g., about 4 vol. % hydrogen mixed with nitrogen) until the temperature is stabilized. The coated substrate may be heated for about 60 minutes at about 350° C. After the forming gas and heater are turned off, the tube may be purged with an inert gas (e.g., nitrogen) to cool the substrate (e.g., to below about 100° C.). The substrate with the thermally sintered conductor may be removed from the quartz tube. Alternatively, the thermal sintering 206 may be performed under any of the other conditions described herein.

In process block 208, the dried and/or thermally sintered metallic composition may be photosintered. A high voltage flash xenon lamp may be used for photosintering. Photosintering may be achieved at temperatures of less than about 100° C. (e.g., ambient temperature, or about 20° C.), to yield a conductor with reduced electrical resistivity and increased adhesion to the substrate. The photosintering process may be performed in an ambient environment (i.e., one in which the environment is not controlled to be different than typical earth environment, and thus will include normal ambient oxygen levels), or within a controlled environment, such as in a forming gas or an inert gas chamber. If performed in an ambient environment, then the organic coating on the particles will inhibit the further formation of a metal oxide coating on the particles. U.S. Patent Application Publication No. 2008/0286488, which is incorporated by reference herein, describes an example of a photosintering process.

Note that the process 200 may be performed on any of the substrates disclosed herein utilizing any of the disclosed compositions. Further, deposition of the compositions may be performed in any manner disclosed herein. Further, the process 200 may be alternatively performed with any combination of the process blocks 204, 206, and/or 208.

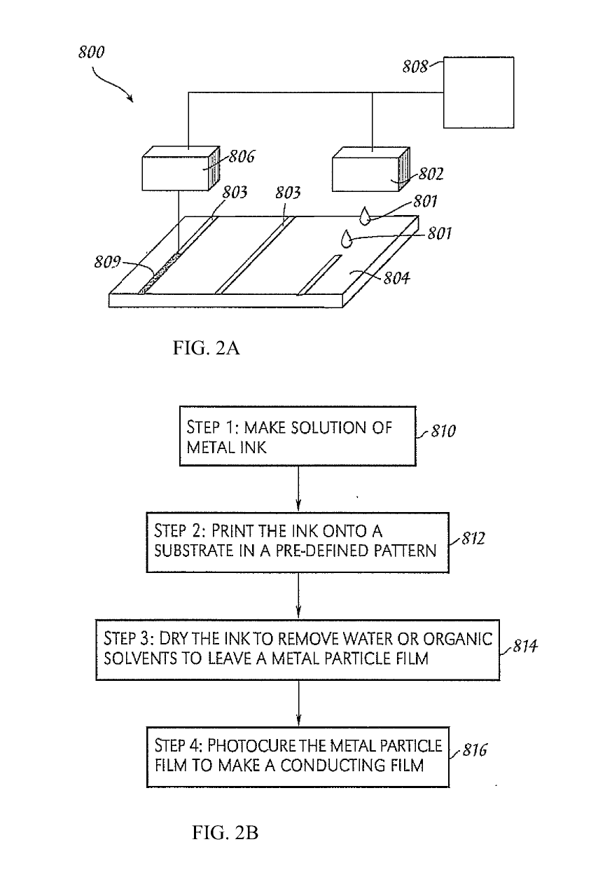

Referring to FIG. 2A, a device 800 is shown for simultaneous or near-simultaneous inkjetting and photosintering (also referred to herein as “photo-curing”) of compositions (copper or any other suitable metal ink) produced in accordance with embodiments of the present disclosure. The device includes an inkjet dispenser 802 for depositing a composition 801 onto the surface of a substrate 804. The device 800 also includes a light source 806 for photosintering the composition 803 deposited by the inkjet dispenser 802. In some implementations, the dispenser 802 may be arranged to automatically pass over the substrate along a predetermined pathway to form patterns of the deposited composition 803. Additionally, the dispenser 802 can be arranged to dispense the composition at multiple predetermined positions and times above the substrate 804. The light source 806 can be attached to the inkjet dispenser 802 or arranged to travel over the substrate 804 separately from the dispenser 802. The light source 806 can be arranged to photosinter the deposited composition 803 immediately after it is deposited by the dispenser 802. Alternatively, the light source 806 can be arranged to photosinter the films at predetermined times following the deposition of the composition 803. The motion of the light source 806 and the dispenser 802 can be controlled by a computer system/controller arrangement 808. A user may program the computer 808 such that the controller automatically translates the dispenser 802 and light source 806 over a predetermined path. In some implementations, the light source 806 and dispenser 802 are fixed and the substrate is placed on a movable platform controlled by the computer/controller 808. Device 800 may alternatively screen print the composition 803 onto the substrate 804.

A flow chart of a photosintering process is shown in FIG. 2B. A solution of a metallic composition configured in accordance with embodiments of the present disclosure is mixed (810) and then printed or dispensed (812) as a film onto the substrate 804 using the dispenser 802. The film deposition may be tightly controlled so a well-defined pattern is formed. The film may then be dried (814) to eliminate water or solvents.

As disclosed herein, in some cases, a thermal sintering step can be introduced subsequent to dispensing the film and prior to the photosintering step. The substrate and deposited film can be thermally sintered using an oven or by placing the substrate on the surface of a heater, such as a hot plate. For example, in some implementations, the film is thermally sintered in air at about 100° C. for 30 minutes before photosintering. Alternatively, the thermal sintering can be performed by directing a laser onto the surface of the film. Following the drying and/or thermal sintering step, a laser beam or focused light from the light source 806 may be directed (816) onto the surface of the film in a process known as direct writing. The light serves to photosinter the film such that it has low resistivity.

It is contemplated that any embodiment discussed in this specification can be implemented with respect to any method, kit, reagent, or composition of the invention, and vice versa. Furthermore, compositions of the invention can be used to achieve methods of the invention.

The singular forms “a,” “an,” and “the” include plural referents unless the context clearly dictates otherwise.

As used herein with respect to an identified property or circumstance, “substantially” refers to a degree of deviation that is sufficiently small so as to not measurably detract from the identified property or circumstance. The exact degree of deviation allowable may in some cases depend on the specific context.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in this specification and attached claims are approximations that can vary depending upon the desired properties sought to be obtained by the presently disclosed subject matter.

As used herein, the term “about,” when referring to a value or to an amount of mass, weight, time, volume, concentration or percentage is meant to encompass variations of in some embodiments ±20%, in some embodiments ±10%, in some embodiments ±5%, in some embodiments ±1%, in some embodiments ±0.5%, and in some embodiments ±0.1% from the specified amount, as such variations are appropriate to perform the disclosed method.

As used herein, “significance” or “significant” relates to a statistical analysis of the probability that there is a non-random association between two or more entities. To determine whether or not a relationship is “significant” or has “significance,” statistical manipulations of the data can be performed to calculate a probability, expressed as a “p value.” Those p values that fall below a user-defined cutoff point are regarded as significant. In some embodiments, a p value less than or equal to 0.05, in some embodiments less than 0.01, in some embodiments less than 0.005, and in some embodiments less than 0.001, are regarded as significant. Accordingly, a p value greater than or equal to 0.05 is considered not significant.

As used herein, the term “and/or” when used in the context of a listing of entities, refers to the entities being present singly or in combination. Thus, for example, the phrase “A, B, C, and/or D” includes A, B, C, and D individually, but also includes any and all combinations and subcombinations of A, B, C, and D. The term “comprising,” which is synonymous with “including,” “containing,” or “characterized by,” is inclusive or open-ended and does not exclude additional, unrecited elements or method steps. “Comprising” is a term of art used in claim language which means that the named elements are present, but other elements can be added and still form a construct or method within the scope of the claim.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a defacto equivalent of any other member of the same list solely based on their presentation in a common group without indications to the contrary.

Concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a numerical range of approximately 1 to approximately 4.5 should be interpreted to include not only the explicitly recited limits of 1 to approximately 4.5, but also to include individual numerals such as 2, 3, 4, and sub-ranges such as 1 to 3, 2 to 4, etc. The same principle applies to ranges reciting only one numerical value, such as “less than approximately 4.5,” which should be interpreted to include all of the above-recited values and ranges. Further, such an interpretation should apply regardless of the breadth of the range or the characteristic being described.

Any steps recited in any method or process claims may be executed in any order and are not limited to the order presented in the claims. Means-plus-function or step-plus function limitations will only be employed where for a specific claim limitation all of the following conditions are present in that limitation: a) “means for” or “step for” is expressly recited; and b) a corresponding function is expressly recited. The structure, material or acts that support the means-plus function are expressly recited in the description herein. Accordingly, the scope of the invention should be determined solely by the appended claims and their legal equivalents, rather than by the descriptions and examples given herein.

What is claimed is:

1. A method for forming a conductive film comprising:
depositing a metallic composition onto a polymeric substrate, wherein the metallic composition comprises metallic particles with an organic material coated on surfaces of the metallic particles;
drying the deposited metallic composition to partially decompose the organic material coating the surfaces of the metallic particles; and
photosintering the deposited metallic composition to form the conductive film on the polymeric substrate, wherein during the photosintering the partially decomposed organic material coating on the surfaces of the metallic particles enhances an adhesion of the conductive film to the polymeric substrate.

2. The method as recited in claim 1, wherein the polymeric substrate comprises a polyimide.

3. The method as recited in claim 2, wherein the drying includes thermal sintering of the deposited metallic composition in an inert gas environment containing about 10-1000 parts per billion of oxygen at a temperature significantly greater than room temperature, and wherein the photosintering is performed at substantially room temperature and within an ambient environment.

4. The method as recited in claim 3, wherein the metallic particles are copper particles, and the conductive film has a resistivity of about 5-9×10⁻⁶.

5. The method as recited in claim 4, wherein the conductive film has an adhesion to the polymeric substrate of about 5 B on an ASTM D 3359 test.

6. The method as recited in claim 1, wherein the organic material coating the surfaces of the metallic particles is selected from the group consisting of self-assembled monolayers, surface-adsorbed organic molecules, polymer materials, and combinations thereof.

7. The method as recited in claim 1, wherein the organic material passivates the surfaces of the metallic particles within the deposited metallic composition previous to drying of the metallic composition.

8. The method as recited in claim 7, wherein the organic material inhibits metal oxide formation on the surfaces of the metallic particles during the drying of the metallic composition.

9. The method as recited in claim 7, wherein the organic material inhibits metal oxide formation on the surfaces of the metallic particles during the photosintering of the deposited metallic composition.

10. The method as recited in claim 1, wherein the organic material coating the surfaces of the metallic particles comprises a coefficient of thermal expansion (“CTE”) value that is more near a CTE value of the polymeric substrate than a CTE value of the metallic particles.

11. The method as recited in claim 2, wherein the metallic particles are copper particles, and the conductive film has a resistivity of about 6-7×10⁻⁶, and wherein the conductive film has an adhesion to the polymeric substrate of about 5 B on an ASTM D 3359 test.

12. The method as recited in claim 1, wherein the organic material coating the surfaces of the metallic particles comprises ethyl cellulose.

13. The method as recited in claim 12, wherein the polymeric substrate comprises polyethylene terephthalate (“PET”).

14. The method as recited in claim 13, wherein the metallic particles are copper particles, and the conductive film has a resistivity in a range of about 3×10⁻⁴ to 7.7×10⁻⁵, and wherein the conductive film has an adhesion to the polymeric substrate of about 4 B-5 B on an ASTM D 3359 test.

15. The method as recited in claim 13, wherein the copper particles have an average diameter less than 100 nanometers and greater than 10 nanometers.

16. The method as recited in claim 13, wherein the copper particles have an average diameter less than 3 microns and greater than 1 micron.

17. The method as recited in claim 13, wherein during the photosintering the adhesion of the conductive film to the polymeric substrate is enhanced when hydroxyl groups in the ethyl cellulose chemically interact with carbonyl groups in the PET through hydrogen bonding.

18. The method as recited in claim 11, wherein the copper particles have an average diameter less than 100 nanometers and greater than 10 nanometers, and wherein the metallic composition is deposited onto the polyimide substrate with a thickness less than 2 microns.

19. The method as recited in claim 14, wherein the metallic composition is deposited onto the PET substrate with a thickness of about 4-5 microns.

20. The method as recited in claim 1, further comprising depositing the polymeric substrate onto a glass substrate previous to depositing the metallic composition onto the polymeric substrate.
